(19) United States
(12) Patent Application Publication
(10) Pub. No.: US 2007/0034886 A1
(43) Pub. Date: Feb. 15, 2007

(54) PLCC package with integrated lens and method for making the package

(76) Inventors: Boon San Wong, Penang (MY); Bee Khoon Ang, Penang (MY); Chien Chai Lye, Gelugor (MY)

Correspondence Address: AVAGO TECHNOLOGIES, LTD., P.O. BOX 1920, DENVER, CO, 80201-1920, US

(21) Appl. No.: 11/201,503

(22) Filed: Aug. 11, 2005

(51) Int. Cl. H01L 33/00; H01L 21/00

(52) U.S. Cl. 257/98; 257/99; 257/100; 257/E33.059; 257/E33.058; 438/27

(57) ABSTRACT

A plastic leaded chip carrier (PLCC) package includes an encapsulant having a domed portion, which is formed as an integral single piece structure. The encapsulant may be formed using an injection molding process. Another injection molding process may be used to form a structural body of the PLCC package.

### BACKGROUND OF THE INVENTION

Light emitting diodes (“LEDs”) have many advantages over conventional light sources, such as incandescent, halogen and fluorescent lamps. These advantages include longer operating life, lower power consumption and smaller size. Consequently, conventional light sources are increasingly being replaced with LEDs in traditional lighting applications. As an example, LEDs are currently being used in flashlights, traffic signal lights, automotive exterior and interior lights and display devices.

Among the various packages for LEDs, an LED package of interest is the plastic leaded chip carrier (PLCC) package for a surface mount LED. Some PLCC packages have flat tops, while other PLCC packages have domed tops. The domed top PLCC packages are currently produced by attaching lenses on tops of the flat top PLCC packages. This process of producing a conventional domed top PLCC package is described with reference to FIGS. 1A, 1B, 1C and 1D. As illustrated in FIG. 1A, the process begins by providing a flat top PLCC package 10. Next, as illustrated in FIG. 1B, an adhesive material 12 is applied to the top of the flat top PLCC package 10. Next, as illustrated in FIG. 1C, a lens 14 is attached to the top of the flat top PLCC package 10 using the adhesive material 102 to produce a finished domed top PLCC package 16, as shown in FIG. 1D.

A concern with the current process for producing the domed top PLCC packages is that the attached lens may be tilted or not centered correctly, which will reduce the optical efficiency of the package. Another concern is that an excessive amount of adhesive material may be applied to attach the lens, which will also reduce the optical efficiency of the package. The finished packages with one or more of these quality issues may have to be rejected, which would lower the yield of the packages during manufacture. Furthermore, visual inspection of all finished packages is required in order to screen out the problematic packages.

Another concern is that the attached lens can become delaminated from the package at some later time. Such delamination of the attached lens would degrade the performance of the package.

In view of these concerns, there is a need for a domed top PLCC package and method for making the package that addresses at least some of these concerns.

### SUMMARY OF THE INVENTION

A plastic leaded chip carrier (PLCC) package and method for making the package utilizes an encapsulant having a domed portion, which is formed as an integral single piece structure. The encapsulant may be formed using an injection molding process. Another injection molding process may be used to form a structural body of the PLCC package. The domed encapsulant eliminates the need to attach a lens onto the PLCC package, and thus, resolves quality issues associated with an attached lens.

A PLCC package in accordance with an embodiment of the invention comprises a structural body, a light source, first and second leadframes and an encapsulant. The first and second leadframes are attached to the structural body. The light source is mounted onto the first leadframe. The second leadframe is electrically connected to the light source. The encapsulant is attached to the light source and the first and second leadframes. The encapsulant has a domed portion that functions as a lens. The encapsulant is an integral single piece structure.

A method for making a PLCC package in accordance with an embodiment of the invention comprises providing first and second leadframes, mounting a light source, e.g., a light emitting diode die, onto the first leadframe, electrically connecting the light source to the second leadframe, forming an encapsulant over the light source and the first and second leadframes, the encapsulant having a domed portion that functions as a lens, the encapsulant being an integral single piece structure, and forming a structural body on the first and second leadframe.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIGS. 1A-1D illustrate a process of producing a conventional dome top plastic leaded chip carrier (PLCC) package in accordance with the prior art.

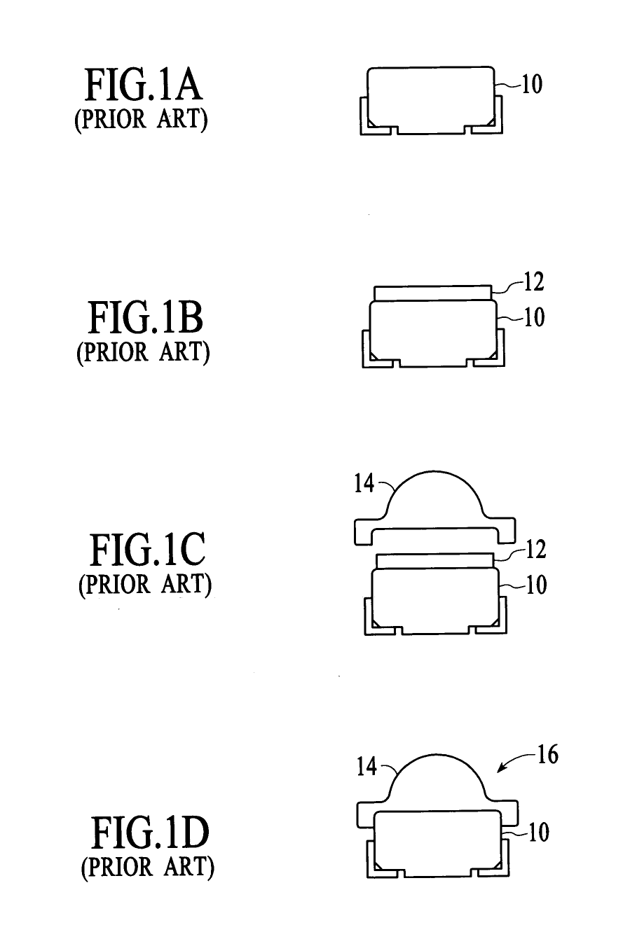

FIG. 2 is a diagram of a domed top PLCC package in accordance with an embodiment of the invention.

FIGS. 3A-3F illustrate a process of producing the PLCC package of FIG. 2 in accordance with an embodiment of the invention.

FIGS. 4A-4F illustrate a process of producing the PLCC package of FIG. 2 in accordance with an alternative embodiment of the invention.

FIG. 5 is a process flow diagram of a method for making a domed top PLCC package in accordance with an embodiment of the invention.

### DETAILED DESCRIPTION

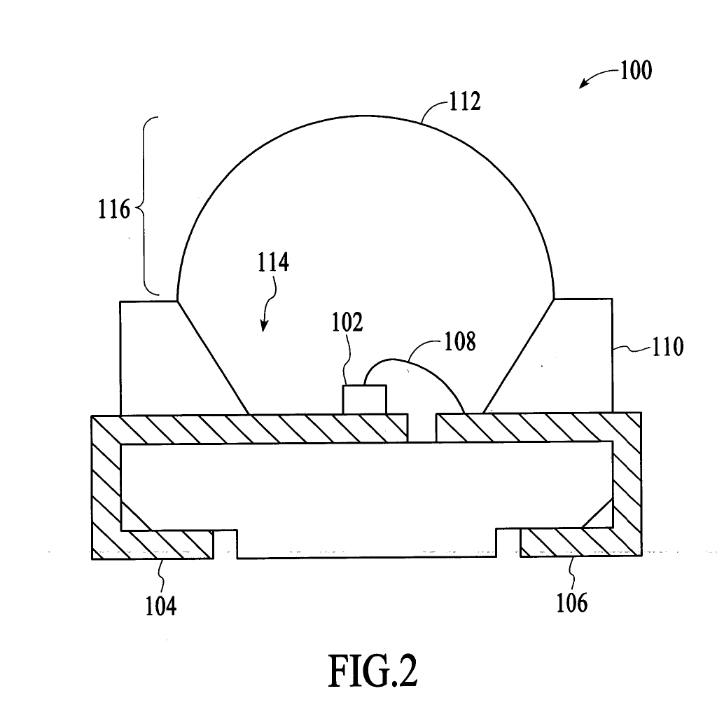

With reference to FIG. 2, a domed top plastic leaded chip carrier (PLCC) package 100 in accordance with an embodiment of the invention is described. FIG. 2 is a cross-sectional view of the PLCC package 100. In this embodiment, the dimensions of the PLCC package 100 conform to the PLCC-4 standard. In other embodiments, the dimensions of the PLCC package 100 may conform to other PLCC standards. The PLCC package 100 is compatible to conventional domed top PLCC packages with attached lenses. However, the PLCC package 100 do not have the quality issues associated with attached lenses, as is the case for the conventional domed top PLCC packages. The PLCC package 100 may be used in a variety of lighting applications. As an example, the PLCC package 100 may be used in automotive exterior lighting, such as turn signals, side repeaters, rear combination lamps and center stoplights, and in automotive interior lighting, such as backlighting for instrument panels and central consoles. The PLCC package 100 may also be used to illuminate various electronic displays, such as traffic signs.

The PLCC package 100 includes a light emitting diode (LED) die 102, leadframes 104 and 106, a bond wire 108, a structural body 110 and a domed encapsulant 112. The LED die 102 is a semiconductor chip that generates light in response to applied driving current. Thus, the LED die 102 is a light source of the PLCC package 100. As an example, the LED die 102 may be a transparent-substrate aluminum indium gallium phosphide (TS AlInGaP) LED die. Although the PLCC package 100 is shown in FIG. 2 as having only a single LED die, the PLCC package may include multiple LED dies. The LED die 102 is attached or mounted onto the leadframe 104 using an adhesive material, which is electrically conductive. Thus, the LED die 102 is electrically connected to the leadframe 104. The LED die 102 is also electrically connected to the other leadframe 106 via the bond wire 108. The leadframes 104 and 106 are made of an electrically and thermally conductive material. The leadframes 104 and 106 provide an electrical path through the LED die 102 so that the LED die can be activated by applied electrical current. The leadframe 104 also provides a thermal path from the mounted LED die 102 to dissipate heat generated by the LED die.

The structural body 110 of the PLCC package 100 holds the leadframes 104 and 106 together. Thus, the structural body 110 provides structural integrity for the LED package 100. The structural body 110 may be made of an electrically insulating material, such as a polymer-based material. The structural body 110 is shaped to include a depression 114 over the leadframes 104 and 106, which serves as a reflector cup. The LED die 102 on the leadframe 104 is positioned within the reflector cup 114 so that light emitted from the LED die can be reflected upward as useful output light. The structural body 110 may be formed by a single injection molding process. In this embodiment, the dimensions of the structural body 110 conform to the PLCC-4 standard. However, in other embodiments, the dimensions of the structural body 110 may conform to other PLCC-4 standards.

The domed encapsulant 112 of the PLCC package 100 is positioned over the LED die 102, the bond wire 108 and the leadframes 104 and 106. The domed encapsulant 112 fills the reflector cup 114, and is attached to the LED die 102, the bond wire 108 and exposed portions of the leadframes 104 and 106 within the reflector cup. The domed portion 116 of the encapsulant 112 protrudes from the reflector cup 114. The domed portion 116 of the encapsulant 112 functions as a lens to focus the light emitted from the LED die 102. The domed encapsulant 112 is an integral single piece structure. That is, the domed encapsulant 112 is formed as a single complete structure, not formed from multiple structures that are attached together. The domed encapsulant 112 can be made of any optically transparent material. As an example, the domed encapsulant 112 can be made of epoxy, silicone, a hybrid of silicone and epoxy, amorphous polyamide resin or fluorocarbon, glass and/or plastic material. In an embodiment, the domed encapsulant 112 is formed by a single injection molding process.

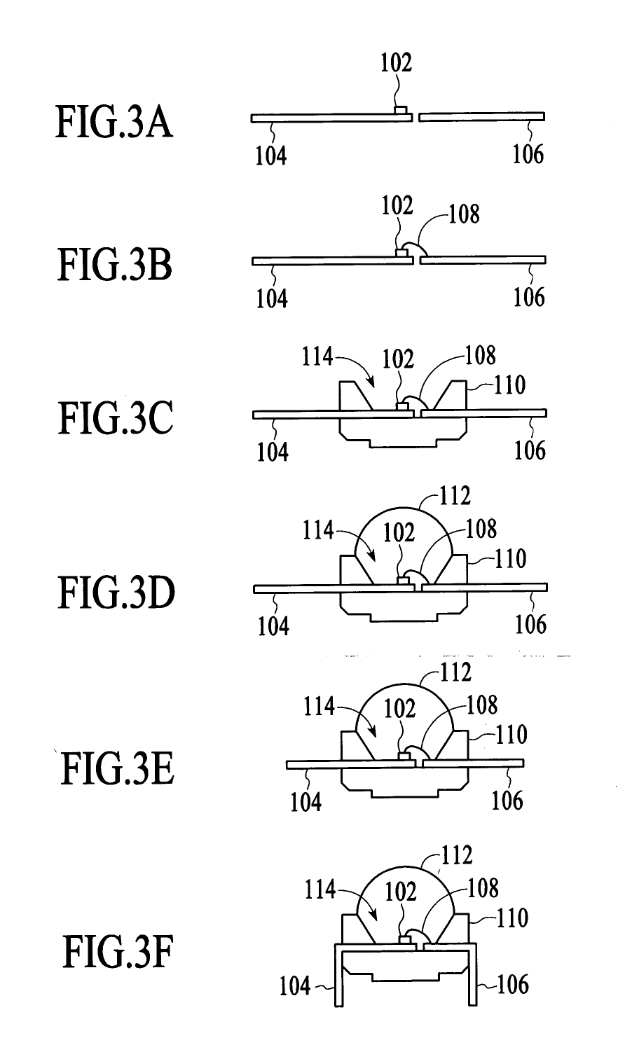

A fabrication process for producing the PLCC package 100 of FIG. 2 in accordance with an embodiment of the invention is described with reference to FIGS. 3A-3F, as well as FIG. 2. As illustrated in FIG. 3A, the fabrication process begins by mounting the LED die 102 onto the leadframe 104 using an appropriate adhesive material. Next, as illustrated in FIG. 3B, the LED die 102 is wire bonded to the leadframe 106 using the bond wire 108. Thus, the LED die 102 is electrically connected to the leadframe 106. Next, as illustrated in FIG. 3C, the structural body 110 is formed on the leadframes 104 and 106 around the LED die 102 and the bond wire 108 such that portions of the leadframes are located within the structural body. The forming of the structural body 110 includes creating the reflector cup 114 and positioning the reflector cup such that the LED die 102 is positioned within the reflector cup. In this embodiment, the structural body 110 is formed using an injection molding process. However, in other embodiments, the structural body 110 may be formed using a different fabrication procedure.

After the structural body 110 is formed, the domed encapsulant 112 is formed over the LED die 102, the bond wire 108 and exposed portions of the leadframes 104 and 106 within the reflector cup 114 of the structural body, as illustrated in FIG. 3D. The domed encapsulant 112 is formed in a single processing step. Since the domed portion (“lens”) of the encapsulant 112 is an integral part of the encapsulant, there are no lens attachment issues for the resulting package, as is the case for conventional dome top PLCC packages. In this embodiment, the domed encapsulant 112 is formed using an injection molding process. However, in other embodiments, the domed encapsulant 112 may be formed using a different fabrication procedure.

After the domed encapsulant 112 is formed, the leadframes 104 and 106 are trimmed, as illustrated in FIG. 3E. Next, as illustrated in FIG. 3F, the leadframes 104 and 106 are bent to configure the leadframes into the desired shapes. When the leadframes 104 and 106 are bent to the desired shapes, the finished PLCC package 100 is produced, as shown in FIG. 2.

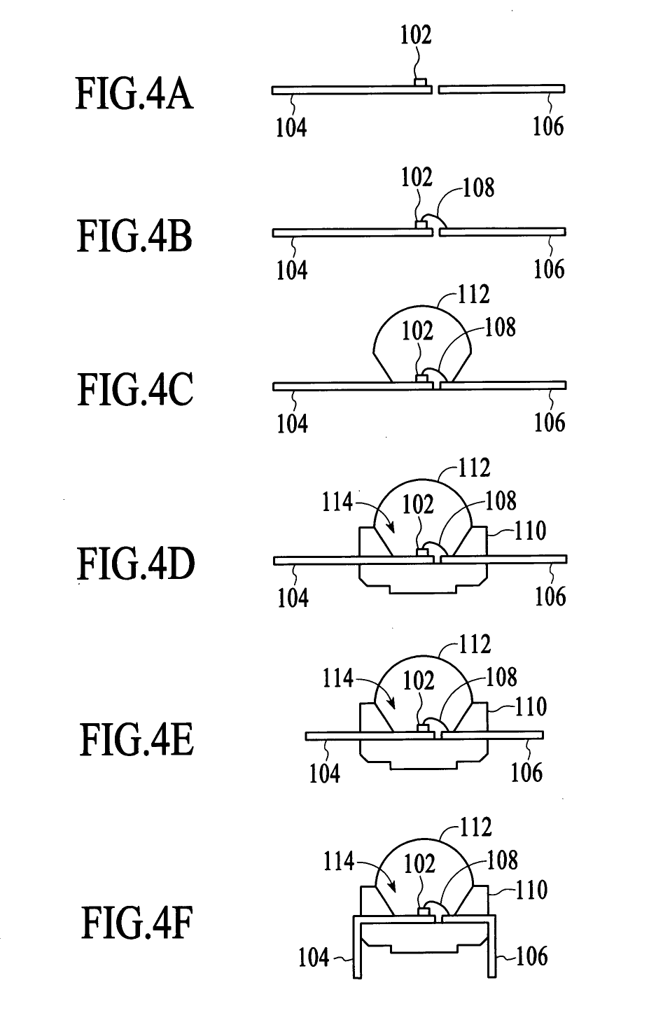

A fabrication process for making the PLCC package 100 of FIG. 2 in accordance with an alternative embodiment of the invention is described with reference to FIGS. 4A-4F, as well as FIG. 2. As illustrated in FIG. 4A, the fabrication process in accordance with the alternative embodiment begins by mounting the LED die 102 onto the leadframe 104 using an appropriate adhesive material. Next, as illustrated in FIG. 4B, the LED die 102 is wire bonded to the leadframe 106 using the bond wire 108. Next, as illustrated in FIG. 4C, the domed encapsulant 112 is formed over the LED die 102, the bond wire 108 and the leadframes 104 and 106. In this embodiment, the domed encapsulant 112 is formed using an injection molding process. However, in other embodiments, the domed encapsulant 112 may be formed using a different fabrication procedure. Next, as illustrated in FIG. 4D, the structural body 110 is formed on the leadframes 104 and 106 around the LED die 102 and the bond wire 108 such that portions of the leadframes are located within the structural body and the domed encapsulant 112 is attached to the structural body. The structural body 110 is also formed on the non-domed portion of the domed encapsulant 112, creating the reflector cup 114. In this embodiment, the structural body 110 is formed using an injection molding process. However, in other embodiments, the structural body 110 may be formed using a different fabrication procedure. Next, as illustrated in FIG. 4E, the leadframes 104 and 106 are trimmed. Next, as illustrated in FIG. 4F, the leadframes 104 and 106 are bent to configure the leadframes into the desired shapes to produce the finished PLCC package 100, as shown in FIG. 2.

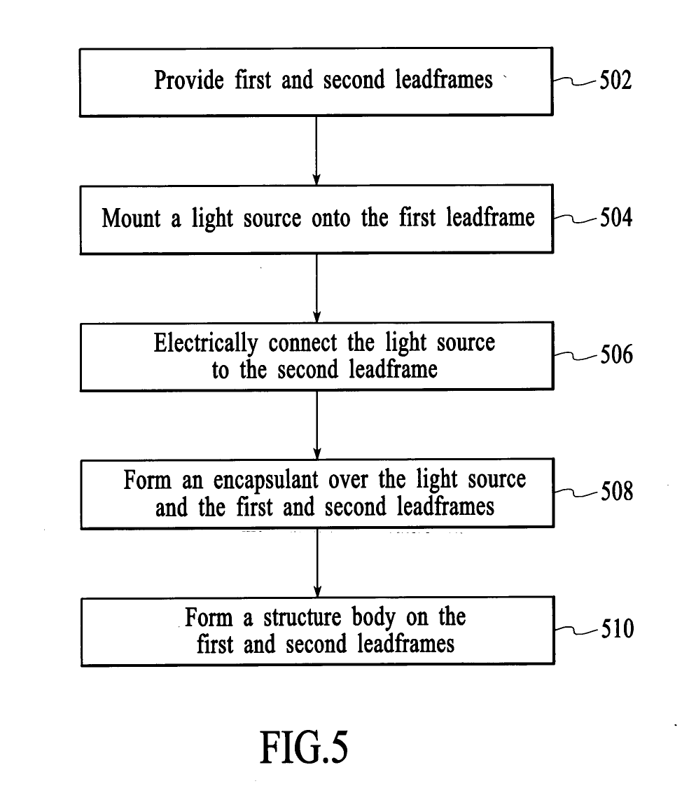

A method for making a PLCC package in accordance with an embodiment of the invention is described with reference to the process flow diagram of FIG. 5. At block 502, first and second leadframes are provided. Next, at block 504, a light source is mounted onto the first leadframe. The light source may be a LED die. Next, at block 506, the light source is electrically connected to the second leadframe. Next, at block 508, an encapsulant is formed over the light source and the first and second leadframes. The encapsulant is formed as an integral single piece structure. The formed encapsulant has a domed portion that functions as a lens. In an embodiment, the encapsulant is formed using an injection molding process. Next, at block 510, a structural body is formed on the first and second leadframes. The structural body may be formed using an injection molding process. In an alternative embodiment, the structural body may be formed prior to the encapsulant.

Although specific embodiments of the invention have been described and illustrated, the invention is not to be limited to the specific forms or arrangements of parts so described and illustrated. The scope of the invention is to be defined by the claims appended hereto and their equivalents.

1. A plastic leaded chip carrier (PLCC) package comprising:
a PLCC structural body;
a first leadframe attached to said PLCC structural body;
a light source mounted onto said first leadframe;
a second leadframe attached to said PLCC structural body, said second leadframe being electrically connected to said light source; and
an encapsulant attached to said light source and said first and second leadframes, said encapsulant having a domed portion that functions as a lens, said encapsulant being an integral single piece structure.

2. The PLCC package of claim 1 wherein said light source includes a light emitting diode die.

3. The PLCC package of claim 1 wherein said encapsulant includes a material selected from a group consisting of epoxy, silicone, a hybrid of silicone and epoxy, amorphous polyamide resin or fluorocarbon, glass and plastic.

4. The PLCC package of claim 1 wherein said PLCC structural body is an integral single piece structure having a depression that serves as a reflector cup, said PLCC structural body being configured to surround said light source such that said light source is positioned in said depression over a portion of said PLCC structural body.

5. (cancel).

6. The PLCC package of claim 1 wherein said PLCC structural body has dimensions that conform to the PLCC-4 standard.

7. A method for making a plastic leaded chip carrier (PLCC) package, said method comprising:
providing first and second leadframes;
mounting a light source onto said first leadframe;
electrically connecting said light source to said second leadframe;
forming an encapsulant over said light source and said first and second leadframes, said encapsulant having a domed portion that functions as a lens, said encapsulant being an integral single piece structure; and
forming a structural body on said first and second leadframe.

8. The method of claim 7 wherein said mounting includes mounting a light emitting diode die onto said first leadframe.

9. The method of claim 7 wherein said forming said encapsulant includes performing an injection molding process to form said encapsulant.

10. The method of claim 9 wherein said forming said structural body includes performing another injection molding process to form said structural body.

11. The method of claim 10 wherein said injection molding process to form said encapsulant is performed prior to said another injection molding process to form said structural body.

12. The method of claim 10 wherein said another injection molding process to form said structural body is performed prior to said injection molding process to form said encapsulant.

13. The method of claim 7 wherein said forming said encapsulant includes forming said encapsulant using a material selected from a group consisting of epoxy, silicone, a hybrid of silicone and epoxy, amorphous polyamide resin or fluorocarbon, glass and plastic.

14. The method of claim 7 wherein said forming said structural body includes creating a reflector cup on said structural body.

15. The method of claim 14 wherein said forming said structural body includes positioning said reflector cup such that said light source is positioned within said reflector cup of said structural body.

16. The method of claim 7 wherein said forming said structural body includes performing an injection molding process to form said structural body.

17. The method of claim 7 wherein said forming said structural body includes forming said structural body such that dimensions of said structural body conform to the PLCC-4 standard.

18. A method for making a plastic leaded chip carrier (PLCC) package, said method comprising:
providing first and second leadframes;
mounting a light emitting diode die onto said first leadframe;
electrically connecting said light emitting diode die to said second leadframe;
forming an encapsulant over said light emitting diode die and said first and second leadframes using an injection molding process, said encapsulant having a domed portion that functions as a lens, said encapsulant being an integral single piece structure; and
forming a structural body on said first and second leadframe using another injection molding process.

19. The method of claim 18 wherein said another injection molding process to form said structural body is performed prior to said injection molding process to form said encapsulant.

20. The method of claim 18 wherein said forming said structural body includes forming said structural body such that dimensions of said structural body conform to the PLCC-4 standard.
